(19) United States
(12) Patent Application Publication
(10) Pub. No.: US 2026/0237959 A1
(43) Pub. Date: Aug. 13, 2026

(54) METHOD FOR PRODUCING A SEMICONDUCTOR LASER AND SEMICONDUCTOR LASER

(71) Applicant: ams-OSRAM International GmbH, Regensburg (DE)

(72) Inventors: Lars NAEHLE, Bad Abbach (DE); Sven GERHARD, Alteglofsheim (DE)

(21) Appl. No.: 19/474,031

(22) PCT Filed: Apr. 12, 2024
(86) PCT No.: PCT/EP2024/059991

§ 371 Date: Oct. 9, 2025

(30) Foreign Application Priority Data
Apr. 13, 2023 (DE) 10 2023 109 382.7

(51) Int. Cl. H01S 5/02; H01S 5/22

(52) U.S. Cl. CPC H01S 5/0203; H01S 5/22

(57) ABSTRACT

A method for producing at least one semiconductor laser includes providing a semiconductor layer sequence including at least one ridge waveguide and a widened region. A main extension direction of the widened region runs transversely or perpendicularly to a main extension direction of the ridge waveguide. The method also includes forming at least one main structure of the semiconductor laser from the widened region. The main structure is connected to the ridge waveguide and includes an outcoupling facet of the semiconductor laser. The main structure is of stepped design, and/or at least one secondary structure is formed from the widened region. The secondary structure is laterally spaced apart from the main structure.

A method for producing a semiconductor laser and a semiconductor laser are specified.

The facets of semiconductor lasers can be produced, for example, by breaking a semiconductor layer sequence and thus during singulation of the semiconductor lasers in the semiconductor laser array. Alternatively, the facets of semiconductor lasers can be produced before singulation by means of etching. In this case, for example, depending on a semiconductor layer sequence or an atomic concentration in the semiconductor layer sequence, overetched portions into the active region of the semiconductor layer sequence can arise.

It is an object to be achieved to specify a method for producing a semiconductor laser, with which a semiconductor laser can be produced efficiently. A further object to be achieved is to specify an improved semiconductor laser.

The objects are achieved by the subject matter of the independent claims. Advantageous implementations and developments are specified in the dependent claims.

According to at least one embodiment, the method for producing at least one semiconductor laser comprises providing a semiconductor layer sequence.

The semiconductor layer sequence can comprise a first semiconductor layer of a first conduction type and a second semiconductor layer of a second conduction type. By way of example, the first semiconductor layer is p-doped and the second semiconductor layer is n-doped or vice versa.

An active region can be arranged between the first semiconductor layer and the second semiconductor layer. The active region is configured, for example, for generating electromagnetic radiation, for example radiation in the ultraviolet, visible or infrared spectral range. The active region can comprise, for example, a p-n junction, a quantum well structure and/or a multi-quantum well structure. By way of example, the semiconductor layer sequence comprises a III-V semiconductor material, for example GaN or AlInGaN, or a II-VI semiconductor material.

The semiconductor layer sequence can have a stacking direction. By way of example, the first semiconductor layer, the active region and the second semiconductor layer are arranged in succession, for example directly in succession, along the stacking direction.

The semiconductor layer sequence comprises, for example, a main extension plane. The stacking direction of the semiconductor layer sequence can run perpendicularly or approximately perpendicularly to the main extension plane of the semiconductor layer sequence.

The semiconductor layer sequence can be provided on a carrier. By way of example, providing the semiconductor layer sequence comprises successively growing the semiconductor layers of the semiconductor layer sequence onto a growth substrate. The carrier can be the growth substrate. Alternatively, the carrier is, for example, a carrier different from the growth substrate.

According to at least one embodiment of the method for producing at least one semiconductor laser, the semiconductor layer sequence comprises at least one ridge waveguide.

The at least one ridge waveguide can be formed at least partially from the semiconductor layer sequence. The at least one ridge waveguide, hereinafter also the ridge waveguide, can be an elevation of the semiconductor layer sequence along a vertical direction. The vertical direction runs, for example, parallel to the stacking direction of the semiconductor layer sequence. In other words, the semiconductor layer sequence can have an elevation, for example a locally delimited elevation, which can be the ridge waveguide. The elevation is arranged, for example, on the side of the semiconductor layer sequence facing away from the carrier.

The ridge waveguide can have a main extension direction. The main extension direction of the ridge waveguide runs, for example, at least in places parallel or approximately parallel to the main extension plane of the semiconductor layer sequence. For example, the ridge waveguide is elongate, in particular formed in a ridge-shaped manner. In a plan view of the semiconductor layer sequence, the ridge waveguide can, for example, be at least approximately rectangular.

The semiconductor layer sequence can comprise more than one ridge waveguide. For example, the semiconductor layer sequence comprises at least two ridge waveguides. The two ridge waveguides can be formed laterally spaced apart from one another. For example, the at least two ridge waveguides can run parallel or approximately parallel to one another. In other words, the main extension direction of the ridge waveguide can run at least in places parallel or approximately parallel to a main extension direction of a further ridge waveguide. By way of example, the semiconductor layer sequence comprises a plurality of ridge waveguides, for example the ridge waveguide, and a plurality of further ridge waveguides. The further ridge waveguides can have the same properties as the ridge waveguide, or as the at least one ridge waveguide.

A lateral direction is understood to mean a direction which runs, in particular, parallel to the main extension plane of the semiconductor layer sequence. A vertical direction is generally understood to mean a direction which is directed perpendicularly to the main extension plane of the semiconductor layer sequence. The vertical direction and the lateral direction are transverse, for instance orthogonal, to one another.

According to at least one embodiment of the method for producing at least one semiconductor laser, the semiconductor layer sequence has a widened region. The widened region can have a structure, for example a layer stack, which corresponds completely or at least approximately to the structure of the ridge waveguide. For example, the widened region is a region of the ridge waveguide in which the ridge waveguide has a greater extension along a direction transverse or perpendicular to the main extension direction of the ridge waveguide than in regions of the ridge waveguide outside the widened region. The extension of the ridge waveguide outside the widened region is, for example, a width of the ridge waveguide. The ridge waveguide can be formed in one piece with the widened region.

For example, at least two ridge waveguides can comprise the widened region. The widened regions of the ridge waveguides can then, for example, be connected to one another or formed spaced apart from one another. By way of example, the semiconductor layer sequence comprises a continuously formed widened region, in particular merely one continuously formed widened region.

According to at least one embodiment of the method for producing at least one semiconductor laser, a main extension direction of the widened region runs transversely or perpendicularly to a main extension direction of the ridge waveguide. The main extension direction of the ridge waveguide can be, for example, the direction along which the ridge waveguide has the greatest extension. By way of example, the main extension direction of the ridge waveguide runs parallel or virtually parallel to a resonator of the semiconductor laser. The resonator of the semiconductor laser is arranged, for example, between two resonator surfaces. By way of example, one of the resonator surfaces comprises an outcoupling facet of the semiconductor laser. The main extension direction of the widened region can run transversely or perpendicularly to the main extension direction of the ridge waveguide. By way of example, the widened region can intersect the at least one ridge waveguide.

According to at least one embodiment, the method for producing at least one semiconductor laser comprises forming at least one main structure of the semiconductor laser from the widened region. The at least one main structure can thus be formed from the material of the widened region. The at least one main structure can be formed by structuring the widened region, for example. By way of example, a recess is produced in the widened region during the structuring of the widened region. By way of example, a side surface/side surfaces of the main structure is/are formed and/or the main structure is/are defined during the production of the recess. The side surfaces of the main structure can hereinafter also be referred to as a side surface of the main structure. The side surface of the main structure can then comprise all surfaces of the main structure which extend perpendicularly or at least approximately perpendicularly to the main extension plane of the semiconductor layer sequence. The side surface of the main structure can, for example, directly adjoin the recess and laterally delimit the recess at least in places.

Alternatively, more than one recess can also be formed. The recesses are then arranged, for example, spaced apart from one another. In particular, each recess can be arranged between a first partial region and a second partial region of a ridge waveguide.

The recess can, for example, be formed such that it extends in places through the semiconductor layer sequence. By way of example, the recess also extends into the carrier. The recess can, for example, separate the ridge waveguide into a first partial region and a second partial region of the ridge waveguide. In other words, the recess can be arranged between the first partial region and the second partial region of the ridge waveguide. The recess in the widened region can, for example, be produced by dry-chemical etching. The side surface of the main structure can therefore comprise etching traces.

The recess can terminate flush with the widened region in a direction parallel to the main extension direction of the ridge waveguide. Alternatively, the recess can project beyond the widened region along this direction at least in places, for example by at least 1 μm, for example by at least 5 μm. The recess can project beyond the widened region for example by a maximum of 50 μm, for example by a maximum of 30 μm or by a maximum of 10 μm. It is also possible for the recess to be arranged completely within the widened region in the lateral direction. A width of an edge of the widened region surrounding the recess can then be between 0.1 μm inclusive and 5 μm inclusive, for example between 0.2 μm inclusive and 3 μm inclusive.

A side of the main structure facing away from the recess adjoins the ridge waveguide at least in places, for example. It is possible for the side of the main structure facing away from the recess to directly adjoin the ridge waveguide. For example, the main structure extends the ridge waveguide. The main structure is arranged, for example, in an optically active region of the semiconductor laser. In contrast to an optically passive region of the semiconductor laser, the optically active region of the semiconductor laser can be a region of the semiconductor laser in which electromagnetic radiation is coupled out during operation of the semiconductor laser.

The main structure can thus be, for example, a structured region of the widened region which directly adjoins the ridge waveguide. The main structure can be designed as part of the widened region and/or as part of the ridge waveguide. The side surface of the main structure runs in a curved or bent manner at least in places in the lateral direction. The main structure can project beyond the recess along the main extension direction of the ridge waveguide. In other words, the main structure is formed, for example, as a projection from the widened region. The projection projects, for example, a length between 1 μm inclusive and 60 μm inclusive, for example between 5 μm inclusive and 30 μm inclusive, into the recess. For example, the side surface of the main structure then runs at least in places transversely or perpendicularly to the main extension direction of the widened region.

According to at least one embodiment of the method for producing at least one semiconductor laser, the main structure is connected to the ridge waveguide. By way of example, the main structure can adjoin, in particular directly adjoin, the ridge waveguide. Alternatively or additionally, the main structure can be formed in one piece with the ridge waveguide.

The ridge waveguide can merge into the main structure. This can mean that the main structure is arranged at least in places along the main extension direction of the ridge waveguide. By way of example, the main structure directly follows the ridge waveguide along the main extension direction of the ridge waveguide. The edge of the widened region can be arranged between the ridge waveguide and the main structure. The resonator can be formed by the main structure, for example. In particular, a resonator length of the semiconductor laser can be defined by the main structure.

By way of example, the resonator length results from a length of the ridge waveguide along the main extension direction of the ridge waveguide and an extent of the main structure along the main extension direction of the ridge waveguide. By way of example, the length of the ridge waveguide along the main extension direction of the ridge waveguide can lie in the range from 100 μm to 1500 μm. The main structure can extend the length of the ridge waveguide along the main extension direction of the ridge waveguide by at most 60 μm, for example, in order to define the resonator length of the semiconductor laser.

According to at least one embodiment of the method for producing at least one semiconductor laser, the main structure comprises an outcoupling facet of the semiconductor laser. A region of the side surface of the main structure which runs, for example, perpendicularly or approximately perpendicularly to the main extension direction of the ridge waveguide comprises, for example, the resonator surface or the outcoupling facet. The outcoupling facet of the semiconductor laser can have a crystal plane which runs perpendicularly or approximately perpendicularly to the main extension direction of the ridge waveguide.

The outcoupling facet is, for example, the side of the main structure facing away from the ridge waveguide. The side surface of the main structure can be formed at least partially by the resonator surface and/or the outcoupling facet. The outcoupling facet is, for example, the surface of the semiconductor laser at which electromagnetic radiation is coupled out of the semiconductor laser during operation of the semiconductor laser.

According to at least one embodiment of the method for producing at least one semiconductor laser, the main structure is of stepped design. By way of example, the main structure comprises two steps, for example at least two steps. The main structure can also comprise at least three steps or a plurality of steps.

The steps of the main structure are arranged, for example, along the main extension direction of the ridge waveguide. In this case, a first step can be arranged closest to the ridge waveguide. Thus, the first step can be arranged along the main extension direction of the ridge waveguide, for example, between the ridge waveguide and a further step. By way of example, the further step is arranged between the outcoupling facet of the main structure and the first step. Alternatively or additionally, the further step can comprise the outcoupling facet.

The steps can be characterized, for example, in that the steps have different extensions along a direction perpendicular or approximately perpendicular to the main extension direction of the ridge waveguide. Alternatively or additionally, the step can project beyond the further step in a lateral direction parallel to the main extension direction of the widened region, or vice versa. In other words, the step-shaped main structure can have steps and/or a multiplicity of angles and direction changes in plan view.

According to at least one embodiment of the method for producing at least one semiconductor laser, at least one secondary structure is formed from the widened region. For example, the secondary structure is laterally spaced apart from the main structure.

The feature that the at least one secondary structure is formed from the widened region can mean that the at least one secondary structure consists of the material of the widened region. The secondary structure can thus be designed as part of the widened region. For example, the secondary structure is not designed as part of the ridge waveguide and is spaced apart from the ridge waveguide. In particular, the secondary structure is located laterally from the ridge waveguide. In other words, the ridge waveguide does not merge into the secondary structure. For example, the secondary structure does not comprise a side surface at which electromagnetic radiation generated during operation of the semiconductor laser is coupled out. The at least one secondary structure can be formed with the same method as the main structure and/or in a common method with the main structure, for example. In other words, all features disclosed for forming the main structure can be used for forming the secondary structure and vice versa.

By way of example, the side surface of the secondary structure is formed during the production of the recess. The recess can be produced by dry-chemical etching. The side surface of the secondary structure can laterally delimit the recess at least in places. The side surface of the secondary structure can then comprise all surfaces of the secondary structure which extend perpendicularly or at least approximately perpendicularly to the main extension plane of the semiconductor layer sequence. By way of example, two partial regions of the side surface of the secondary structure can form an angle which is different from 180°. In other words, the side surface of the secondary structure can run, for example in a plan view of the semiconductor layer sequence, at least in places transversely or perpendicularly to the main extension direction of the widened region and/or run in places in a curved and/or bent manner. In plan view, the secondary structure can comprise convex and/or concave structures. In particular, the side surface of the secondary structure can run at least in places in a convex or concave manner. In other words, the secondary structure can be formed, for example, as a projection from the widened region. The secondary structure projects, for example, a length between 0.5 μm inclusive and 60 μm inclusive, for example between 5 μm inclusive and 30 μm inclusive, into the recess.

The secondary structure can be arranged spaced apart from the main structure. By way of example, the secondary structure is arranged in the optically passive region of the semiconductor laser. The optically passive region can be a region of the semiconductor laser in which no electromagnetic radiation is generated or coupled out during operation. It is possible for the secondary structure not to have a resonator surface and/or outcoupling facet of the semiconductor laser. In particular, no electromagnetic radiation generated in the active region of the semiconductor laser can be coupled out at the secondary structure. By way of example, the secondary structure does not directly adjoin the ridge waveguide. In particular, the secondary structure can be arranged such that the secondary structure does not follow the ridge waveguide along the main extension direction of the ridge waveguide. By way of example, the semiconductor layer sequence comprises two ridge waveguides with main structures arranged thereon. The at least one secondary structure, for example at least two secondary structures, can be arranged between the two main structures. Thus, the widened region can have at least two projections between two main structures.

In at least one embodiment of the method for producing at least one semiconductor laser, a semiconductor layer sequence comprising at least one ridge waveguide and a widened region is provided, wherein a main extension direction of the widened region runs transversely or perpendicularly to a main extension direction of the ridge waveguide. At least one main structure of the semiconductor laser is formed from the widened region, wherein the main structure is connected to the ridge waveguide and comprises an outcoupling facet of the semiconductor laser. The main structure is of stepped design, and/or at least one secondary structure is formed from the widened region, said secondary structure being laterally spaced apart from the main structure.

With the method described here for producing at least one semiconductor laser, a semiconductor laser can be produced efficiently. The at least one semiconductor laser can be produced cost-effectively, inter alia. In particular, the resonator surfaces and/or the outcoupling facet of the semiconductor laser can be produced by means of etching. By forming a stepped main structure or a secondary structure which is laterally spaced apart from the main structure, underetching of the outcoupling facet, in particular in the case of wet-chemical etching for exposing the crystal plane of the outcoupling facet or for smoothing the side surfaces of the main structure and/or of the secondary structure, can be minimized, reduced or prevented. As a result, a high-quality resonator surface or outcoupling facet can be produced efficiently. The wet-chemical etching can therefore be influenced in a targeted manner by a shape of the recess, or a shape of the main structure and/or secondary structure, in order to achieve particularly smooth resonator surfaces by etching. In addition, a plurality of resonator surfaces can be produced at the same time as loss-free as possible.

According to at least one embodiment of the method for producing a semiconductor laser, the outcoupling facet of the semiconductor laser is formed by means of wet-chemical etching.

By means of the wet-chemical etching, not only material can be removed in the vertical direction, but also in the lateral direction. The material can be the layers of the semiconductor layer sequence. In the wet-chemical etching, the material of the semiconductor layer sequence can be etched, for example, along the lateral direction. For example, the side surface of the main structure is smoothed during the wet-chemical etching. An average roughness of the side surface of the main structure after the wet-chemical etching is, for example, a maximum of 50 nm, for example a maximum of 30 nm or for example a maximum of 10 nm. In particular, the root mean square roughness (RMS) is, for example, a maximum of 10 nm, for example a maximum of 2 nm or for example a maximum of 1 nm. By means of the wet-chemical etching of the side surface of the main structure, for example, the resonator surface and/or the outcoupling facet of the semiconductor laser can be formed. The side surface of the main structure can have, in places, in particular merely in places, a crystal plane which runs perpendicularly or virtually perpendicularly to the main extension direction of the ridge waveguide. The crystal plane running perpendicularly to the main extension direction of the ridge waveguide is exposed at the side surfaces of the main structure, for example, by means of the wet-chemical etching. The outcoupling facet can have, for example, etching traces.

The outcoupling facet can thus be etched into individual semiconductor lasers before singulation of a semiconductor laser array. In particular, the outcoupling facet is not produced only during singulation, for example, by breaking.

According to at least one embodiment, the at least one secondary structure is of trapezoidal or semicircular design in a plan view of the semiconductor layer sequence.

The secondary structure can then have at least two crystal planes. By way of example, the side surface of the secondary structure facing the recess has at least one direction change. During the direction change, the side surface of the secondary structure can run in a curved and/or bent manner. The secondary structure can be of semicircular design, for example, in a plan view. The secondary structure then has, for example, a multiplicity of direction changes. Alternatively, the secondary structure can be of step-shaped design and, for example, have a trapezoidal or semicircular outline in a plan view. It is possible for all side surfaces of the secondary structure to have etching traces. For example, in the finished semiconductor laser, all exposed side surfaces of the secondary structure can have etching traces.

By means of the multiplicity of direction changes, the occurrence of underetchings, or overetched portions, during the production of the resonator surfaces, for example of the outcoupling facet, by wet-chemical etching can be reduced or prevented.

Alternatively or additionally, the main structure can be of trapezoidal or semicircular design in a plan view.

According to at least one embodiment of the method for producing a semiconductor laser, the semiconductor layer sequence comprises at least two ridge waveguides, wherein at least two main structures are formed in the widened region, and at least two secondary structures are formed in the widened region, wherein the at least two secondary structures are arranged between the main structure and an adjacent further main structure. The at least two main structures are formed on the at least two ridge waveguides, for example. In particular, a main structure can be formed on each ridge waveguide. Alternatively or additionally, at least one main structure can be formed on each region of the ridge waveguide which later forms a semiconductor laser. The fact that two main structures are adjacent can mean, in particular, that no further main structure is arranged between them. However, at least one secondary structure or a plurality of secondary structures can be arranged between two adjacent main structures.

By means of the formation of at least two secondary structures, the recess in the widened region can have a structuring by means of which a high-quality resonator surface, for example the outcoupling facet of the semiconductor laser, can be produced by means of wet-chemical etching.

According to at least one embodiment of the method for producing a semiconductor laser, the main structure and the at least one secondary structure are formed in a common etching method.

The main structure and the secondary structure of the semiconductor laser can be formed by a dry-chemical etching method, for example by plasma etching. In this case, by way of example, regions of the widened region from which no main structure or secondary structure of the semiconductor laser is formed are removed by means of dry-chemical etching.

In other words, the widened region can be structured by means of dry-chemical etching, wherein regions of the widened region which form the at least one main structure and the at least one secondary structure of the semiconductor laser remain. In particular, the regions of the widened region which form the at least one main structure and the at least one secondary structure of the semiconductor laser are not removed during the production of the recess.

By way of example, the main structure and the secondary structure are formed before the wet-chemical etching of the resonator surfaces. However, it is also possible for the main structure and the secondary structure to be produced successively by means of dry-chemical etching.

By way of example, the side surfaces of the main structure and of the secondary structure are smoothed in a common wet-chemical etching method. During the wet-chemical etching, it is possible for overetched portions to arise spontaneously during the wet-chemical etching depending on a structure or a structure of the semiconductor layer sequence and/or on account of an atomic concentration in the semiconductor layer sequence. These overetched portions can arise, for example, in the active region.

By virtue of the fact that the main structure and the secondary structure are formed before the wet-chemical etching, the occurrence of overetched portions can be prevented or at least reduced. This is achieved, for example, by the presence of a plurality of different crystal planes at the secondary structure and/or the main structure. Lateral propagation of overetched portions is slowed down, for example, at convex and/or concave structures. By means of the secondary structures, for example, the etching behavior during the wet-chemical etching at the outcoupling facet can be influenced. The facet quality, for example of the outcoupling facet, can be increased by avoiding overetched portions.

According to at least one embodiment, the main structure has, at least in places, a crystal plane which runs perpendicularly to the main extension direction of the ridge waveguide and forms the outcoupling facet. At a crystal plane running perpendicularly to the main extension direction of the ridge waveguide, the electromagnetic radiation generated by the active region can be coupled out efficiently from the semiconductor laser.

According to at least one embodiment, the main structure has at least two steps along the main extension direction of the ridge waveguide. The side surface of the main structure can run in a convex and/or concave manner, in particular in a curved or bent manner, in the region of the two steps and/or in a transition from the first step to the further step. By virtue of this, the occurrence of overetched portions during wet-chemical etching can be prevented.

According to at least one embodiment of the method for producing a semiconductor laser, a first step arranged closest to the ridge waveguide has a lateral extension which is smaller than an extension of a further step which is located between the first step and the outcoupling facet.

By way of example, the first step has a lateral extension which is smaller than the width of the ridge waveguide. The main structure can then have an undercut in a plan view of the resonator surface.

By forming an undercut, for example, different crystal planes and/or a multiplicity of direction changes are formed. During the wet-chemical etching, these can have a positive influence on the quality of the resonator surface of the semiconductor laser by virtue of an overetched portion being slowed down by the multiplicity of direction changes, or by the convex and/or concave structures of the main structure.

According to at least one embodiment of the method for producing a semiconductor laser, the widened region is structured in the lateral direction before the at least one main structure and/or the at least one secondary structure is formed. The structuring has, for example, at least one transition at which a side surface of the widened region runs in a curved and/or bent manner.

The widened region has, for example, at least one notch which extends in the direction away from the later-formed outcoupling facet of the semiconductor laser. The widened region can have a multiplicity of notches. For example, a side surface of the widened region is formed at least approximately in a wave-shaped manner. The notches can be of trapezoidal or semicircular design, for example, in a plan view. The notches extend away from the outoupling facet of the semiconductor laser by at least 2 μm, for example at least 5 μm, for example. For example, the notches project beyond the outcoupling facet by at most 50 μm, for example by at most 30 μm.

According to at least one embodiment of the method for producing a semiconductor laser, a recess is formed in the widened region such that the structure of the recess follows the structuring of the widened region. By way of example, the main structure is formed in a convex manner. Alternatively, it is possible for the main structure to be formed merely by a region of the widened region which is planar in the lateral direction. The secondary structure is formed in a convex or concave manner, for example.

One idea of this embodiment lies, inter alia, in increasing an edge length of the side surface of the main structure and/or of the secondary structure. In addition, different crystal axes can be formed.

According to at least one embodiment of the method for producing a semiconductor laser, a plurality of semiconductor lasers is produced in a common method. The plurality of semiconductor lasers can be singulated into multiple emitters and/or single emitters.

For example, the semiconductor laser array is singulated into semiconductor lasers. A semiconductor laser can then comprise, for example, merely one ridge waveguide, or a region of a ridge waveguide. Alternatively, the semiconductor laser array can be singulated into at least one multiple emitter. The finished semiconductor laser can then comprise more than one ridge waveguide. A main structure comprising an outcoupling facet can be arranged on each ridge waveguide. At least one secondary structure or a plurality of secondary structures can be arranged between the main structures. For example, the semiconductor laser array is separated or singulated along the recess in a direction parallel to the main extension direction of the widened region. It is furthermore possible for the semiconductor laser array to be singulated parallel to the main extension direction of a ridge waveguide. The semiconductor laser array can be separated or singulated between, for example approximately centrally between, two adjacent ridge waveguides.

According to at least one embodiment of the method for producing a semiconductor laser, the at least one secondary structure is formed in the widened region laterally between the main structure and a further main structure. By means of the at least one secondary structure, lateral overetching can be kept away from the facet. A semiconductor laser having an etched outcoupling facet can thus be produced efficiently.

According to at least one embodiment of the method for producing a semiconductor laser, the at least one secondary structure remains completely in the singulated semiconductor laser. If merely one secondary structure is arranged between the main structure and the further main structure, during singulation between the main structures, alternatively, merely approximately half a secondary structure can remain in the singulated semiconductor laser.

Furthermore, a semiconductor laser is specified. The semiconductor laser can be produced, for example, using a method described here. In other words, all features disclosed for the method for producing a semiconductor laser can be used for the semiconductor laser and vice versa.

According to at least one embodiment of the semiconductor laser, the semiconductor laser comprises a semiconductor layer sequence, wherein the semiconductor layer sequence comprises a ridge waveguide and a widened region. A main extension direction of the widened region runs transversely or perpendicularly to a main extension direction of the ridge waveguide. The semiconductor layer sequence comprises a main structure which is connected to the ridge waveguide, wherein the main structure comprises an outcoupling facet of the semiconductor laser and is formed from the widened region.

The main structure is of stepped design. Alternatively or additionally, the semiconductor layer sequence has a secondary structure which is formed from the widened region and is laterally spaced apart from the main structure.

The semiconductor laser described here can have an outcoupling facet produced by means of etching. Said outcoupling facet can be produced efficiently, cost-effectively and in good quality. The efficiency and the functionality of the semiconductor laser can be improved as a result.

According to at least one embodiment of the semiconductor laser, the main structure and/or the secondary structure have/has at least one side surface. The at least one side surface runs, for example, at least partially transversely and/or perpendicularly to the main extension direction of the widened region.

According to at least one embodiment of the semiconductor laser, the secondary structure is at least approximately trapezoidal, quarter-circular or semicircular in a plan view of the semiconductor layer sequence.

According to at least one embodiment of the semiconductor laser, the main structure has at least two steps along the main extension direction of the ridge waveguide.

According to at least one embodiment of the semiconductor laser, the semiconductor laser is designed as a multiple emitter comprising at least two main structures and at least one secondary structure, wherein the secondary structure is arranged spaced apart from the main structures along the main extension direction of the widened region.

The method described here for producing a semiconductor laser and the semiconductor laser described here are explained in more detail below in conjunction with embodiments and the associated figures.

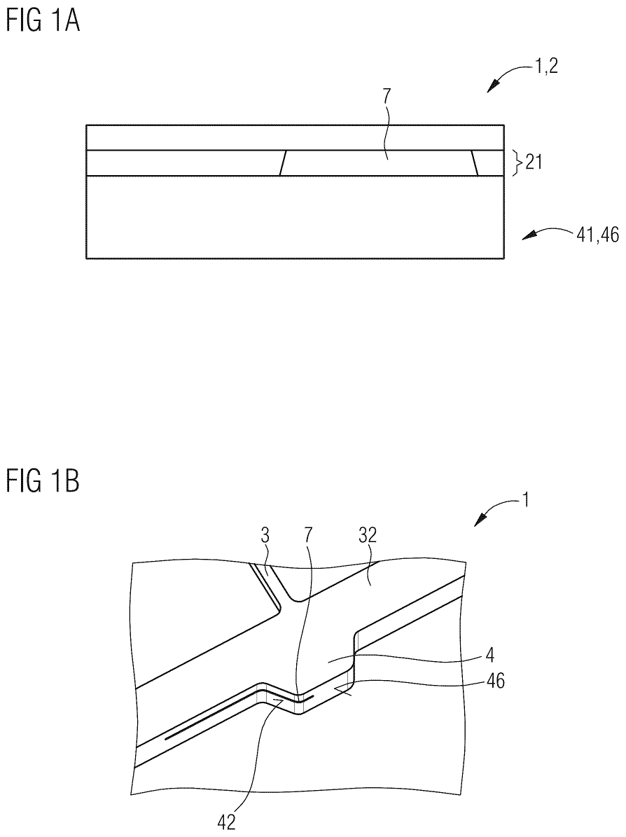

FIGS. 1A and 1B show comparative examples of a semiconductor laser.

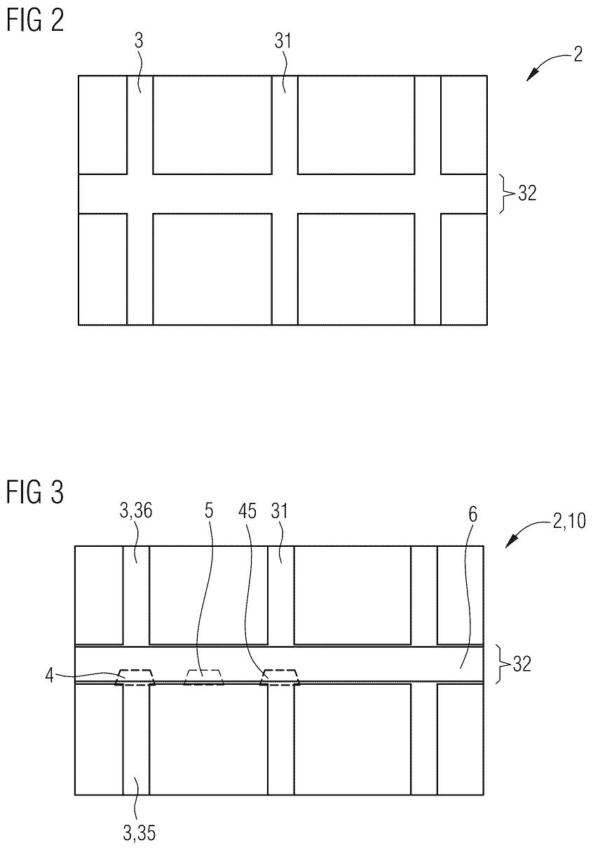

FIGS. 2 to 7 show steps in methods for producing semiconductor lasers in a schematic plan view according to embodiments.

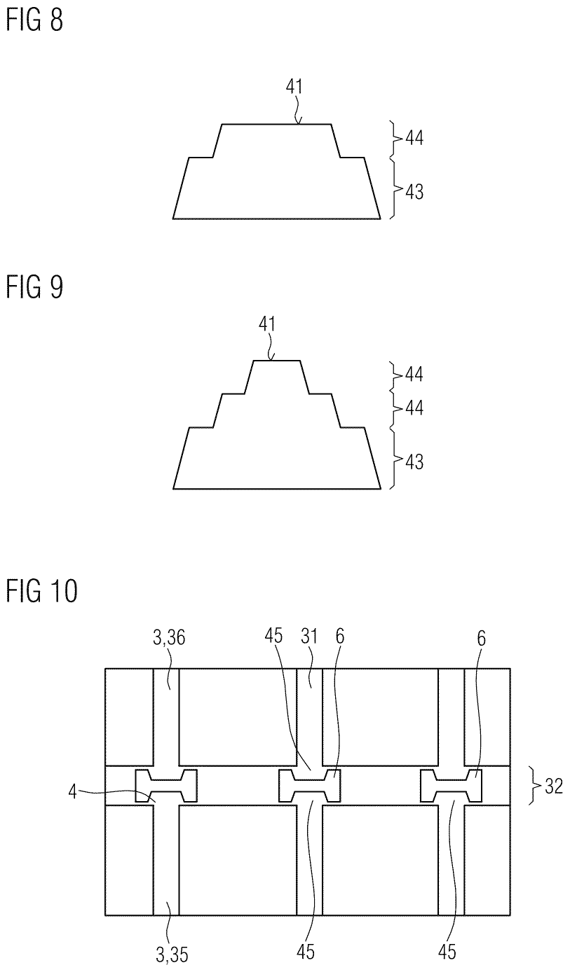

FIGS. 8 and 9 show step-shaped main structures or secondary structures in a schematic plan view according to embodiments. FIGS. 10 to 12 show intermediate steps in methods for producing semiconductor lasers according to embodiments in a schematic plan view.

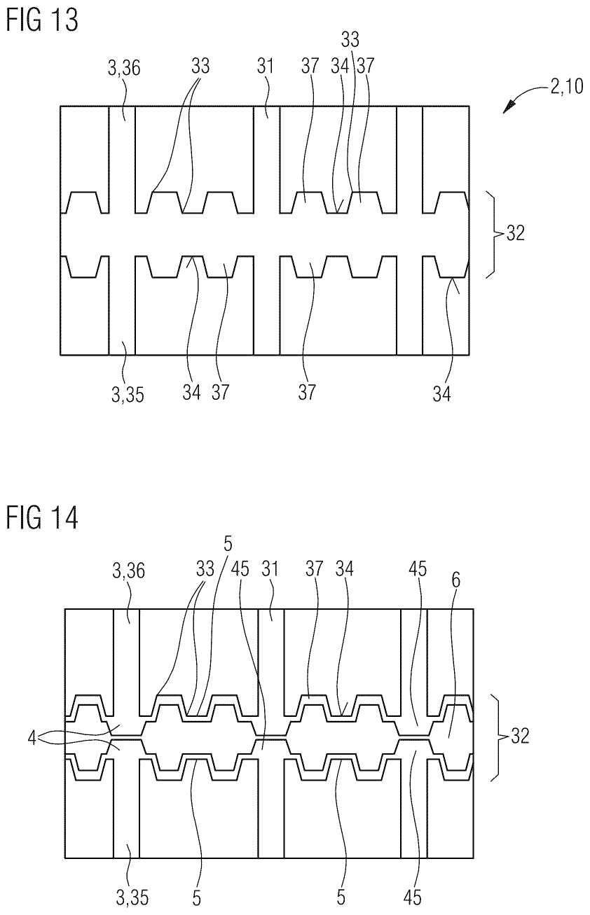

FIGS. 13 to 15 show intermediate steps in methods for producing semiconductor lasers according to further embodiments in a schematic plan view.

FIG. 16 shows an intermediate step in the method for producing a semiconductor laser according to a further embodiment in a schematic plan view.

Identical, similar or identically acting elements are provided with the same reference signs in the figures. The figures and the size ratios of the elements illustrated in the figures with respect to one another are not to be regarded as to scale. Rather, individual elements can be illustrated with an exaggerated size for better illustration and/or for better comprehensibility.

FIG. 1A shows a schematic illustration of a resonator surface 46 of a semiconductor laser 1. In this case, an overetched portion 7 has formed in an active region 21 of a semiconductor layer sequence 2. The overetched portion 7 can have arisen during wet-chemical etching. The resonator surface 46 can thus be partially undercut. The resonator surface 46 of the semiconductor laser 1 can be, for example, a facet of the semiconductor laser 1, in particular an outcoupling facet 41 of the semiconductor laser 1.

FIG. 1B shows a comparative example of a semiconductor laser 1 comprising a resonator surface 46 including an overetched portion 7 in the active region 21 of the semiconductor layer sequence 2. The semiconductor layer sequence 2 comprises a ridge waveguide 3 and a widened region 32. A side surface 42 of a main structure 4 can be partially undercut by the overetched portion 7. One idea of the method described here for producing a semiconductor laser 1 lies in minimizing, reducing or preventing an overetched portion 7 shown in FIG. 1A or 1B.

FIG. 2 shows a schematic plan view of a semiconductor layer sequence 2 in the method for producing a semiconductor laser 1 according to an embodiment. Plan view means here and hereinafter, for example, that the viewing direction runs perpendicularly to a main extension plane of the semiconductor layer sequence 2. In the method step shown here, a semiconductor layer sequence 2 is provided.

The semiconductor layer sequence 2 comprises at least one ridge waveguide 3. The semiconductor layer sequence 2 can comprise at least one further ridge waveguide 31. By way of example, the semiconductor layer sequence 2 comprises a plurality of ridge waveguides 3 and 31. The ridge waveguide 3 and the further ridge waveguide 31 run parallel or approximately parallel to one another.

The semiconductor layer sequence 2 comprises a widened region 32. A main extension direction of the widened region 32 runs transversely or perpendicularly to a main extension direction of the ridge waveguide 3. By way of example, the widened region 32 also runs transversely or perpendicularly to a main extension direction of the further ridge waveguide 31. The widened region 32 can be formed continuously, in particular in one piece. By way of example, the widened regions 32 of the ridge waveguides 3 and 31 form a continuous widened region 32.

FIG. 3 shows a schematic illustration of a further method step in the method for producing a semiconductor laser 1. FIG. 3 shows a semiconductor laser array 10. The method step shown in FIG. 3 follows, for example, the method step shown in FIG. 2. Here, at least one main structure 4 of the semiconductor laser 1 is formed from the widened region 32. The main structure 4 is connected to the ridge waveguide 3. The main structure 4 comprises a resonator surface 46 of the semiconductor laser 1. The resonator surface 46 is, for example, an outcoupling facet 41 of the semiconductor laser 1.

At least one secondary structure 5 can be formed from the widened region 32. The at least one secondary structure 5 can be formed during the formation of the main structure 4. The at least one secondary structure 5 is then laterally spaced apart from the at least one main structure 4. By way of example, the secondary structure 5 is laterally spaced apart from all main structures 4, 45 produced from the widened region 32. The secondary structure 5 is arranged between two adjacent main structures 4, 45.

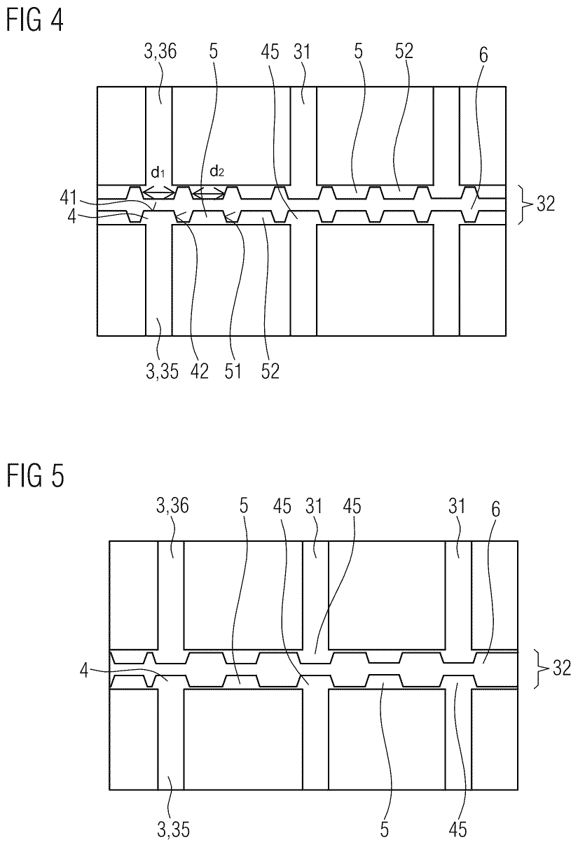

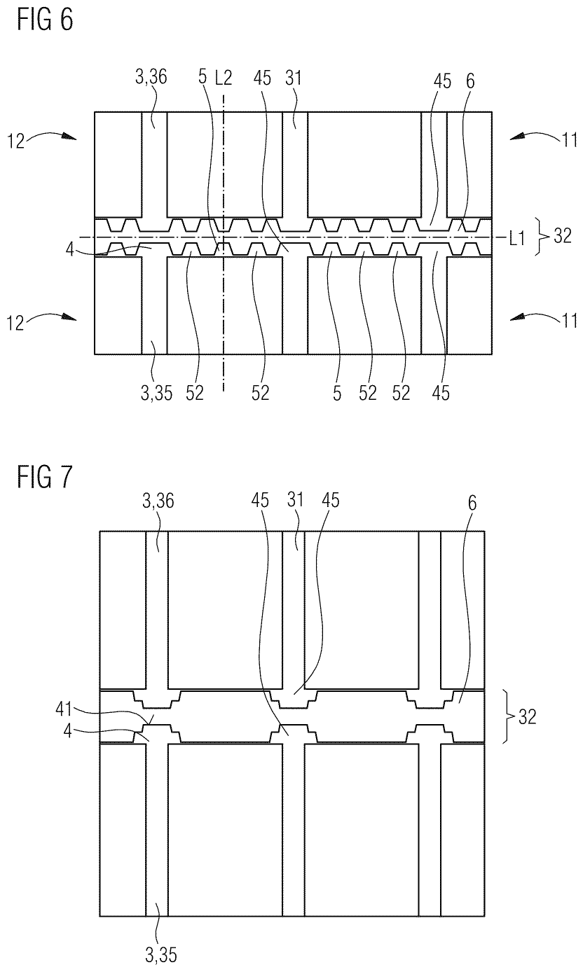

FIG. 4 shows a step in a method for producing a semiconductor laser 1 according to an embodiment in a schematic plan view. The method step illustrated in FIG. 4 involves the finished semiconductor laser array 10, which can be singulated into semiconductor lasers 1, single emitters 12 and/or multiple emitters 11 in a subsequent method step (cf. FIG. 6).

In the embodiment shown here, the at least one main structure 4 and the at least one secondary structure 5 of the semiconductor laser 1 are of trapezoidal design. Alternatively or additionally, the main structures 4, 45 can be formed in a convex and/or concave manner, for example in a step-shaped and/or circular manner, in a plan view. By way of example, at least one main structure 4, 45 is of trapezoidal design, at least one main structure 4, 45 is of circular design and/or at least one main structure 4, 45 is of step-shaped design. All main structures 4, 45 of the semiconductor laser array 10 can have the same or approximately the same shape or at least partially different shapes from one another. The main structure 4 has a side surface 42.

The secondary structure 5 is arranged between two adjacent main structures 4, 45. The secondary structure has a side surface 51. A further secondary structure 52 is arranged between the two adjacent main structures 4, 45. The further secondary structure 52 is arranged between the secondary structure 5 and the further main structure 45.

By way of example, a lateral size d₂ of the secondary structure 5 can be less than or equal to a lateral size d₁ of the main structure 4, 45. By way of example, the lateral size both of the main structure 4, 45 and of the secondary structure 5 can be greater than 1 μm. Furthermore, the lateral size both of the main structure 4, 45 and of the secondary structure can be less than 100 μm.

By way of example, the main structures 4, 45 and/or the secondary structures 5, 52 have been produced or defined in the widened region by forming a recess 6 by means of dry-chemical etching. The recess 6 can extend through the semiconductor layer sequence 2 in the vertical direction. By way of example, the recess 6 extends completely through the semiconductor layer sequence 2 in the vertical direction, for example into a substrate, not shown.

The recess 6 is formed, for example, as a continuous trench in the lateral direction. In other words, the recess 6 in the widened region 32 is formed continuously and extends completely or at least approximately completely over the extent of the widened region 32 in the lateral direction. By way of example, an extent of the recess 6 along the main extension direction of the widened region 32 corresponds at least approximately to the extent of the widened region 32 along the main extension direction of the widened region 32. At least approximately can mean here that the extensions of the recess 6 and of the widened region 32 along the main extension direction of the widened region 32 are identical. Alternatively, the recess 6 can have a smaller extension along the main extension direction of the widened region 32.

The recess 6 extends completely over the width of the ridge waveguide 3. Here, the width of the ridge waveguide 3 is the extension of the ridge waveguide 3 perpendicularly to the main extension direction of the ridge waveguide 3. The recess 6 is arranged between a first partial region 35 of the ridge waveguide 3 and a further partial region 36 of the ridge waveguide 3. The partial regions 35, 36 of the ridge waveguide 3 can be assigned to different semiconductor lasers 1 after singulation of the semiconductor laser array 10.

In the widened region 32, a main structure 4 is arranged on the first partial region 35 of the ridge waveguide 3 and on the further partial region 36 of the ridge waveguide 3, respectively.

The main structure 4 and the secondary structure 5 are formed in a common etching method, for example. The outcoupling facet of the semiconductor laser 1 is produced by means of wet-chemical etching, for example.

FIG. 5 shows a semiconductor laser array 10 according to a further embodiment.

The semiconductor laser array 10 in FIG. 5 differs from the semiconductor laser array 10 illustrated in FIG. 4 in that merely one secondary structure 5 is arranged between two adjacent main structures 4, 45.

FIG. 6 shows a semiconductor laser array 10 according to a further embodiment.

The semiconductor laser array 10 in FIG. 6 differs from the semiconductor laser array 10 illustrated in FIG. 4 in that a secondary structure 5 and two further secondary structures 52 are arranged between the main structure 4 and the further main structure 45. A distance between the main structure 4 and the further main structure 45 can in this case be at least approximately the same in the embodiments in FIGS. 4 to 6. Thus, an extension of the recess 6 between the main structure 4 and the secondary structure 5 or an extension of the secondary structure 5 along the main extension direction of the widened region 32 can be different from one another. In addition, here and in the further embodiments, the main structures 4, 45 and the secondary structures 5, 52 can have different extensions, shapes and distances from one another.

The plurality of semiconductor lasers 1 in the semiconductor laser array 10 can be produced in a common method. Subsequently, the semiconductor laser array 10 can be singulated into multiple emitters 11 and/or single emitters 12. The semiconductor laser array is singulated, for example, along the singulation line L 1 and the singulation line L 2. In this case, at least one secondary structure 5 can remain completely in the singulated semiconductor laser 1.

FIG. 7 shows a semiconductor laser array 10 according to a further embodiment. The semiconductor laser array 10 comprises the ridge waveguide 3 with a first partial region 35 and a further partial region 36 and the further ridge waveguide 31. The further ridge waveguide also comprises a first and a second region. The first region 35 and the further region 36 are formed spaced apart from one another by a recess 6. A main structure 4 is arranged on the first partial region 35 of the ridge waveguide 3. The main structure 4 is of stepped design. The main structure 4 has two steps 43, 44. In particular, the main structure 4 can have at least two steps 43, 44. A first step 43 is the step of the main structure 4 which is arranged closest to the ridge waveguide. A further step 44 is arranged between the outcoupling facet 41 of the main structure 4 and the first step 43. Alternatively or additionally, the further step 44 can comprise the outcoupling facet 41.

FIG. 8 shows a schematic plan view of a step-shaped main structure 4 according to an embodiment. The main structure 4 comprises a first step 43 and a further step 44. Thus, the embodiment of the main structure 4 shown here comprises two steps.

FIG. 9 shows a schematic plan view of a step-shaped main structure 4 according to a further embodiment. In comparison with the embodiment illustrated in FIG. 8, the main structure 4 shown here comprises a first step 43 and two further steps 44. The further step 44 comprises the outcoupling facet 41 of the semiconductor laser 1 on the side facing away from the first step 43.

Alternatively, FIGS. 8 and 9 can also show embodiments of a step-shaped secondary structure 5.

FIGS. 10 to 12 show a schematic plan view of a semiconductor laser array 10 according to an embodiment. In the embodiments of FIGS. 10 to 12, for example, the recess 6 is minimized. As a result, the contact region of the semiconductor layer sequence 2 which is in contact with an etching medium during the wet-chemical etching is minimized. By virtue of this, the occurrence of overetched portions can be reduced or prevented. In the embodiments of FIGS. 10 to 12, secondary structures 5 can also be produced.

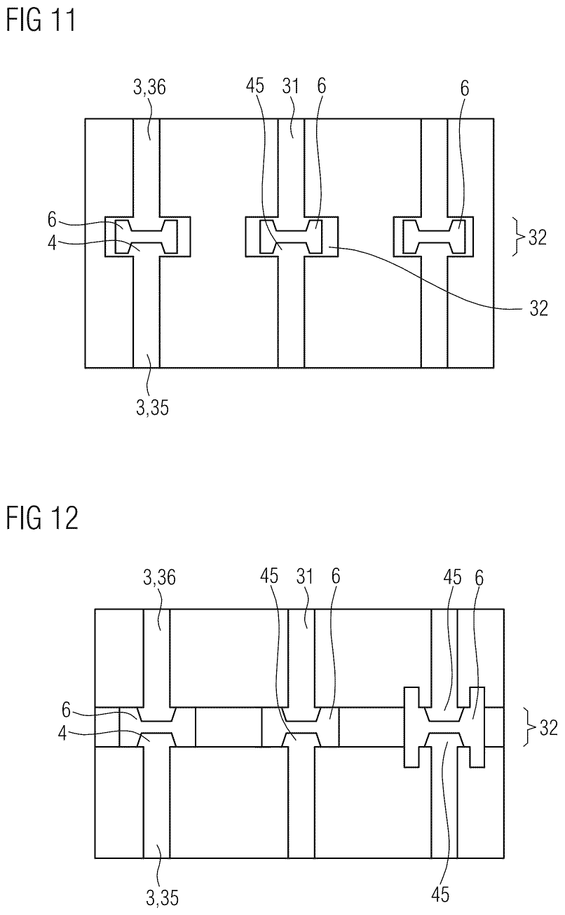

FIG. 10 shows an embodiment of a semiconductor laser array 10 comprising a continuous widened region 32. Alternatively, the widened region 32 can be formed from widened regions which are arranged spaced apart from one another and are shown, for example, in FIG. 11.

In the embodiment of FIG. 12, the right-hand recess 6 projects beyond the widened region 32.

FIG. 13 shows a schematic plan view of the semiconductor layer sequence 2 in a method for producing at least one semiconductor laser 1 according to a further embodiment. The widened region 32 is structured in the lateral direction during the provision of the semiconductor layer sequence 2, that is to say before the at least one main structure 4 and/or the at least one secondary structure 5 is formed, and the structuring comprises at least one transition 33 at which a side face 34 of the widened region 32 runs in a curved and/or bent manner. By way of example, the widened region has notches 37.

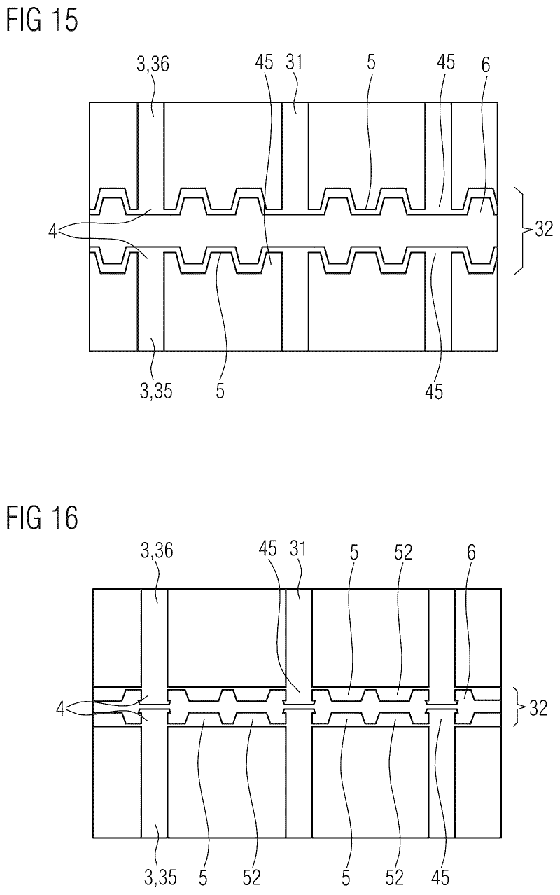

FIGS. 14 and 15 show a schematic plan view of a semiconductor laser array 10 according to a further embodiment. In this case, the semiconductor laser array 10 in FIGS. 14 and 15 was formed by forming at least one main structure 4 and at least one secondary structure 5 from the widened region from the semiconductor layer sequence 2 illustrated in FIG. 13. The recess 6 is formed in the widened region 32 such that the structure of the recess 6 follows the structuring of the widened region 32. In the embodiment of FIG. 14, the main structure 4 was formed as a projection in the widened region 32. The main structure 4 is of stepped design. Alternatively, as shown in FIG. 15, the main structure 4 is not of stepped design. In particular, the side surface of the main structure 4 is defined by the notch 37 of the widened region 32.

FIG. 16 shows a semiconductor laser array 10 according to a further embodiment. The semiconductor laser array 10 comprises a plurality of semiconductor lasers 1 to be produced. The semiconductor laser 1 comprises at least the ridge waveguide 3, wherein a main structure 4 from the widened region 32 is arranged on the ridge waveguide 3. In this case, the main structure 4 is of stepped design. The main structure 4 has a first step 43 arranged closest to the ridge waveguide and a further step 44. The further step 44 is located between the first step 43 and the outcoupling facet 41 of the semiconductor laser 1. The first step 43 has a lateral extension which is smaller than an extension of the further step 44. The semiconductor laser array 10 in FIG. 16 comprises two secondary structures 5, 52 between two adjacent main structures 4, 45, respectively. Alternatively, it is possible for the semiconductor laser array 10 to comprise no, merely one or a multiplicity of secondary structures 5, 52 between adjacent main structures 4, 45.

The features and embodiments described in conjunction with the figures can be combined with one another according to further embodiments, even if not all combinations are explicitly described. Furthermore, the embodiments described in conjunction with the figures can alternatively or additionally have further features according to the description in the general part.

The invention is not restricted to the embodiments by the description of said embodiments. Rather, the invention comprises any novel feature and also any combination of features, which includes in particular any combination of features in the claims, even if this feature or this combination itself is not explicitly specified in the claims or embodiments.

### LIST OF REFERENCES

1 Semiconductor laser
10 semiconductor laser array
11 multiple emitter
12 Single emitter
2 Semiconductor layer sequence
21 active region
3 ridge waveguide
31 further ridge waveguide
32 widened region
33 transition
34 side surface of the widened region
35 first partial region of the ridge waveguide
36 further partial region of the ridge waveguide
37 notch of the widened region
4 main structure
41 outcoupling facet
42 side surface of the main structure
43 First step
44 Further step
45 further main structure
46 resonator surface
5 secondary structure
51 side surface of the secondary structure
52 further secondary structure
6 recess
7 overetched portion
L1 singulation line
L2 further singulation line

1. A method for producing at least one semiconductor laser, comprising:
providing a semiconductor layer sequence comprising at least one ridge waveguide and a widened region, wherein a main extension direction of the widened region runs transversely or perpendicularly to a main extension direction of the ridge waveguide and the widened region is horizontally adjacent to the ridge waveguide, and
forming at least one main structure of the semiconductor laser from the widened region, wherein the main structure is connected to the ridge waveguide and comprises an outcoupling facet of the semiconductor laser wherein the main structure has a larger width than the ridge waveguide along the main extension direction of the widened region, and wherein
the main structure is of stepped design and comprises at least two steps along the main extension direction of the ridge waveguide, and/or
at least one secondary structure is formed from the widened region, said secondary structure being laterally spaced apart from the main structure and having a lateral size along the main extension direction of the widened region that is less than or equal to the lateral size of the main structure.

2. The method for producing a semiconductor laser according to claim 1, wherein the outcoupling facet of the semiconductor laser is formed by means of wet-chemical etching.

3. The method for producing a semiconductor laser according to claim 1, wherein the at least one secondary structure is of trapezoidal or semicircular design in a plan view of the semiconductor layer sequence.

4. The method for producing a semiconductor laser according to claim 1, wherein
the semiconductor layer sequence comprises at least two ridge waveguides,
at least two main structures are formed in the widened region, and
at least two secondary structures are formed in the widened region, wherein the at least two secondary structures are arranged between the main structure and an adjacent further main structure.

5. The method for producing a semiconductor laser according to claim 1, wherein the main structure and the at least one secondary structure are formed in a common etching method.

6. The method for producing a semiconductor laser according to claim 1, wherein the main structure has, at least in places, a crystal plane which runs perpendicularly to the main extension direction of the ridge waveguide and forms the outcoupling facet.

7. The method for producing a semiconductor laser according to claim 1, wherein a first step arranged closest to the ridge waveguide has a lateral extension which is smaller than an extension of a further step which is located between the first step and the outcoupling facet.

8. The method for producing a semiconductor laser according to claim 1, wherein the widened region is structured in the lateral direction before the at least one main structure and/or the at least one secondary structure is formed, and the structuring has at least one transition at which a side face of the widened region runs in a curved and/or bent manner.

9. The method for producing a semiconductor laser according to claim 8, wherein a recess is formed in the widened region such that the structure of the recess follows the structuring of the widened region.

10. The method for producing a semiconductor laser according to claim 1, wherein
a plurality of semiconductor lasers are produced in a common method, and
the plurality of semiconductor lasers is singulated into multiple emitters and/or single emitters.

11. The method for producing a semiconductor laser according to claim 10, wherein the at least one secondary structure is formed in the widened region laterally between the main structure and a further main structure.

12. The method for producing a semiconductor laser according to claim 9, wherein the at least one secondary structure remains completely in the singulated semiconductor laser.

13. A semiconductor laser comprising a semiconductor layer sequence, wherein
the semiconductor layer sequence comprises a ridge waveguide and a widened region,
a main extension direction of the widened region runs transversely or perpendicularly to a main extension direction of the ridge waveguide, and the widened region is horizontally adjacent to the ridge waveguide,
the semiconductor layer sequence comprises a main structure, and
the main structure is connected to the ridge waveguide, comprises an outcoupling facet of the semiconductor laser, the outcoupling facet being formed from the widened region wherein the main structure has a larger width than the ridge waveguide along the main extension direction of the widened region, and wherein
the main structure is of stepped design and comprises at least two steps along the main extension direction of the ridge waveguide, and/or
the semiconductor layer sequence comprises at least one secondary structure which is formed from the widened region and is laterally spaced apart from the main structure and has a lateral size along the main extension direction of the widened region that is less than or equal to the lateral size of the main structure.

14. The semiconductor laser according to claim 13, wherein the main structure and/or the secondary structure comprise at least one side surface, and the at least one side surface runs at least partially transversely and/or perpendicularly to the main extension direction of the widened region.

15. The semiconductor laser according to claim 13, wherein the secondary structure is at least approximately trapezoidal, quarter-circular or semicircular in a plan view of the semiconductor layer sequence.

16. The semiconductor laser according to claim 13, which is designed as a multiple emitter comprising at least two main structures and at least one secondary structure, wherein the secondary structure is arranged spaced apart from the main structures along the main extension direction of the widened region.
